(19) United States
(12) Patent Application Publication
(10) Pub. No.: US 2024/0429880 A1
(43) Pub. Date: Dec. 26, 2024

(54) BIAS CIRCUIT

(71) Applicant: Murata Manufacturing Co., Ltd., Kyoto (JP)

(72) Inventor: Yuri HONDA, Kyoto (JP)

(21) Appl. No.: 18/828,279

(22) Filed: Sep. 9, 2024

Related U.S. Application Data
(63) Continuation of application No. PCT/JP2023/012574, filed on Mar. 28, 2023.

(30) Foreign Application Priority Data
Mar. 29, 2022 (JP) 2022-054314

(51) Int. Cl. H03F 3/21; H03F 1/02; H03F 1/30; H03F 3/45

(52) U.S. Cl. CPC H03F 3/211; H03F 1/0211; H03F 1/30; H03F 3/4508; H03F 3/45179; H03F 2200/451

(57) ABSTRACT

A bias circuit includes a first bias transistor that has a base or a gate that is supplied with a first bias and an emitter or a source that supplies a bias through a first resistor element to a first amplifier, a first diode that has an anode that is connected to the base or the gate of the first bias transistor and a cathode that is electrically connected to the emitter or the source of the first bias transistor, a second resistor element that has a first end connected to the anode of the first diode and a second end connected to the cathode of the first diode, and a capacitor that has a first end connected to the anode of the first diode and a second end connected to a ground. The cathode of the first diode is electrically connected to the ground.

### CROSS REFERENCE TO RELATED APPLICATION

This is a continuation of International Application No. PCT/JP2023/012574 filed on Mar. 28, 2023 which claims priority from Japanese Patent Application No. 2022-054314 filed on Mar. 29, 2022. The contents of these applications are incorporated herein by reference in their entireties.

### BACKGROUND ART

### Technical Field

The present disclosure relates to a bias circuit.

A bias circuit that causes a power transistor to operate in a high power mode or a low power mode has been available (see, for example, Patent Document 1).
Patent Document 1: U.S. Pat. No. 11,121,681

### BRIEF SUMMARY

In the bias circuit described in Patent Document 1, control current may increase and the maximum power of the power transistor may decrease.

The present disclosure provides a bias circuit capable of reducing control current and suppressing a reduction in the maximum power of an amplifier.

A bias circuit according to an aspect of the present disclosure includes a first bias transistor that has a base or a gate that is supplied with a first bias and an emitter or a source that supplies a bias through a first resistor element to a first amplifier, a first diode that has an anode that is connected to the base or the gate of the first bias transistor and a cathode that is electrically connected to the emitter or the source of the first bias transistor, a second resistor element that has a first end that is connected to the anode of the first diode and a second end that is connected to the cathode of the first diode, and a capacitor that has a first end that is connected to the anode of the first diode and a second end that is connected to a ground. The cathode of the first diode is electrically connected to the ground.

According to the present disclosure, a bias circuit capable of reducing control current and suppressing a reduction in the maximum power of an amplifier can be provided.

### BRIEF DESCRIPTION OF THE DRAWINGS

FIG. 1 is a circuit diagram of a power amplifier circuit 101 in a high power mode.

FIG. 2 is a circuit diagram of the power amplifier circuit 101 in a low power mode.

FIG. 3 is a diagram illustrating an example of changes in a DC component Vndc2 of an emitter voltage Vn2 and a DC component Vrdc2 of an emitter voltage of a transistor 912 with respect to output power.

FIG. 4 is a diagram illustrating an example of changes in a DC component Vndc3 of a base voltage Vn3 and a DC component Vrdc3 of a base voltage of a transistor 926 with respect to output power.

FIG. 5 is a diagram illustrating an example of changes in a DC component Vndc1 of a base voltage Vn1 and a DC component Vrdc1 of a base voltage of the transistor 912 with respect to output power.

FIG. 6 is a circuit diagram of a power amplifier circuit 102.

FIG. 7 is a circuit diagram of a power amplifier circuit 103.

FIG. 8 is a circuit diagram of a power amplifier circuit 104.

FIG. 9 is a circuit diagram of a power amplifier circuit 105.

FIG. 10 is a circuit diagram of a power amplifier circuit 106.

FIG. 11 is a circuit diagram of a power amplifier circuit 107.

FIG. 12 is a circuit diagram of a bias supply circuit 910 in a high power mode described as a related art in Patent Document 1.

FIG. 13 is a circuit diagram of the bias supply circuit 910 in a low power mode described as the related art in Patent Document 1.

### DETAILED DESCRIPTION

Hereinafter, embodiments of the present disclosure will be described in detail with reference to drawings. The same elements will be denoted by the same signs and repetitive description will be omitted as much as possible.

### Comparative Example

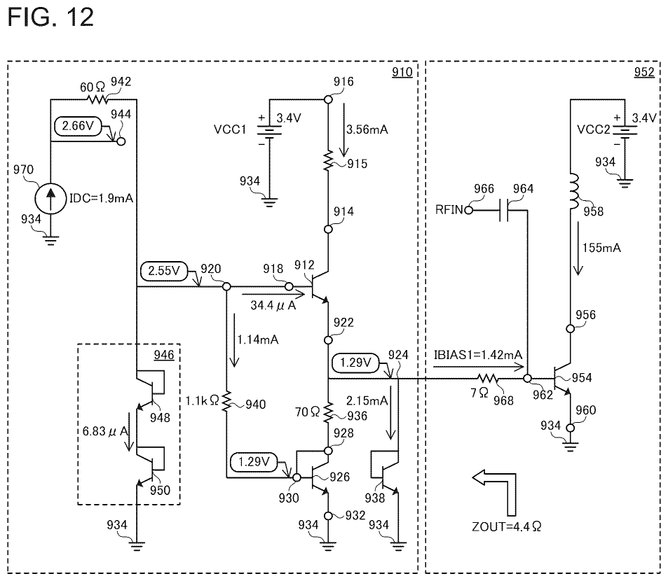

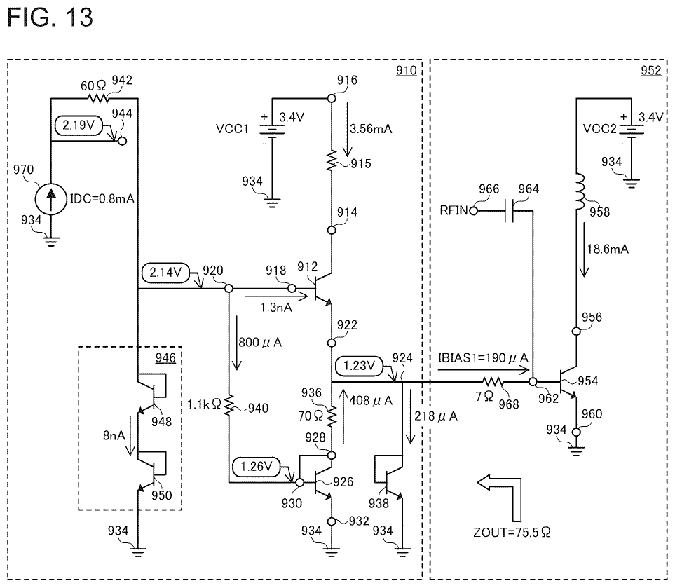

First, a bias supply circuit according to a comparative example will be described. The bias supply circuit according to the comparative example is a bias supply circuit 910 in a high power mode and a low power mode described as a related art in Patent Document 1. FIGS. 12 and 13 are circuit diagrams of the bias supply circuit 910 in the high power mode and the low power mode, respectively, described as the related art in Patent Document 1.

As illustrated in FIG. 12, the bias supply circuit 910 supplies a bias current IBIAS1 to an amplifying transistor 954. In the bias supply circuit 910, a transistor 912 has an emitter that is connected to the base of the amplifying transistor 954 with a resistor element 968 interposed therebetween, a collector that is connected to a power supply with a resistor element 915 interposed therebetween, and a base. A resistor element 940 has a first end that is connected to the base of the transistor 912 and a second end. A transistor 926 has a collector and a base that are connected to the second end of the resistor element 940 and an emitter that is connected to a fixed voltage node 934. A resistor element 936 has a first end that is connected to the emitter of the transistor 912 and a second end that is connected to the collector and the base of the transistor 926. A transistor 938 has a collector and a base that are connected to the emitter of the transistor 912 and an emitter that is connected to the fixed voltage node 934.

A large control current IDC is set in the high power mode. In this mode, no current flows to the resistor element 936, and the base current of the amplifying transistor 954 and the current flowing to the transistor 938 are supplied by the current flowing between the collector and the emitter of the transistor 912. The output impedance of the bias supply circuit 910 ranges from 1Ω to 10Ω.

As illustrated in FIG. 13, in the low power mode, a small control current IDC is set. In this mode, no current flows between the collector and the emitter of the transistor 912. Thus, the base current of the amplifying transistor 954 and the current flowing to the transistor 938 are supplied through the resistor element 940, the base and the collector of the transistor 926, and the resistor element 936. The output impedance of the bias supply circuit 910 corresponds to a value that is approximately the resistance value of the resistor element 936.

However, in the high power mode illustrated in FIG. 12, there are two paths in which the control current IDC flows: a path in which the control current IDC flows through the transistor 926 to the fixed voltage node 934 and a path in which the control current IDC flows through the transistors 948 and 950 to the fixed voltage node 934. Therefore, a large control current IDC is required.

Furthermore, although not illustrated in the drawing, the base of the transistor 912 is typically connected to the fixed voltage node 934 with a capacitor interposed therebetween. Thus, the base of the transistor 912 is substantially short-circuited to the fixed voltage node 934 in terms of an RF (radio frequency) signal. An RF signal input from an RFIN terminal is half-wave rectified due to diode characteristics between the base and the emitter of the transistor 912. Thus, the potential at the emitter of the transistor 912 increases as the level of the RF signal input from the RFIN terminal increases.

In contrast, there is a path in which an RF signal is transmitted: a path in which the RF signal is transmitted through the resistor element 936, the collector and the base of the transistor 926, and the resistor element 940 to the base of the transistor 912. The base of the transistor 912 is connected to the fixed voltage node 934 with a capacitor interposed therebetween. Since the capacitor has a limited impedance, the potential at the base of the transistor 912 oscillates due to an RF signal. Oscillations of the potential at the base of the transistor 912 and oscillations of the potential at the emitter of the transistor 912 have substantially the same phase. Thus, oscillations of the potential at the base of the transistor 912 suppress an increase in the potential at the emitter of the transistor 912. Accordingly, the maximum power of the amplifying transistor 954 decreases.

### First Embodiment

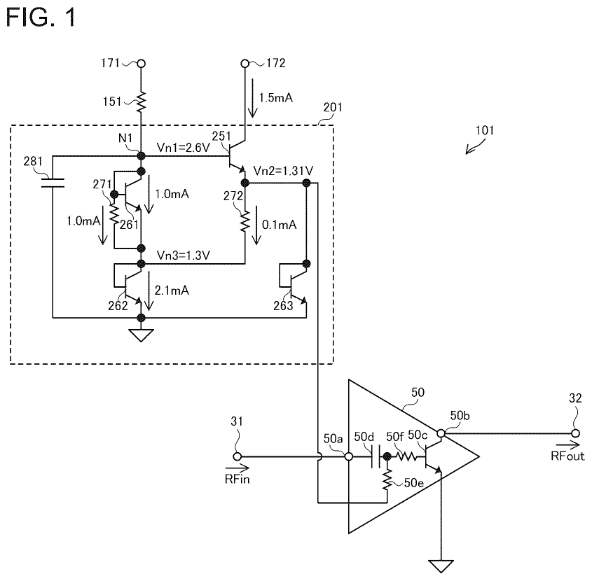

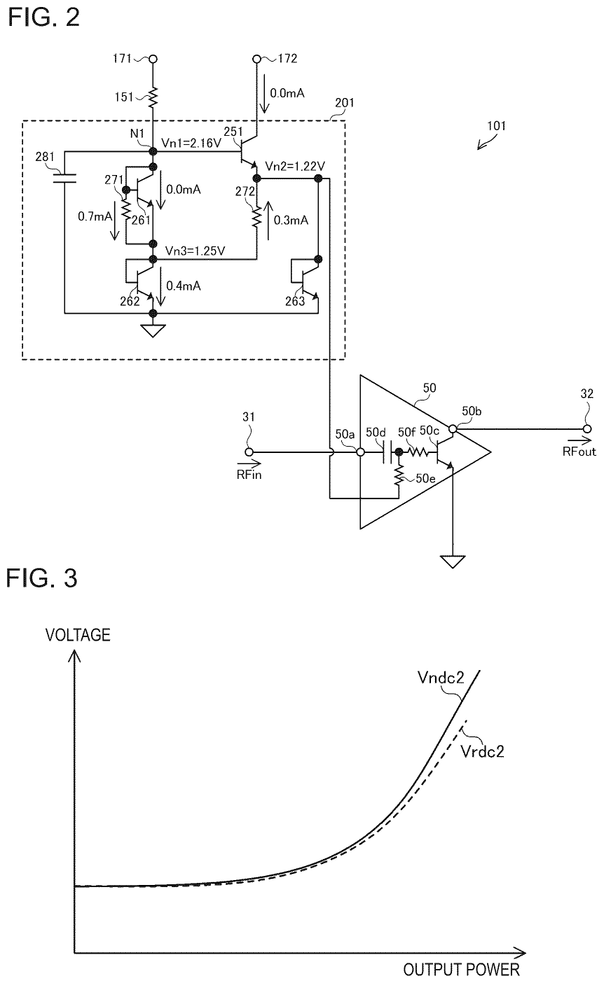

Next, a power amplifier circuit 101 according to a first embodiment will be described. FIG. 1 is a circuit diagram of the power amplifier circuit 101 in a high power mode in which relatively high power is output from an output terminal 32. FIG. 2 is a circuit diagram of the power amplifier circuit 101 in a low power mode in which relatively low power is output from the output terminal 32. As illustrated in FIGS. 1 and 2, the power amplifier circuit 101 is an amplifier circuit that amplifies an input signal RFin supplied to an input terminal 31 and outputs an output signal RFout from the output terminal 32. The input signal RFin is, for example, an RF (radio frequency) signal.

The power amplifier circuit 101 includes an amplifier 50, a bias supply circuit 201, and a resistor element 151. The amplifier 50 includes an input terminal 50a, an output terminal 50b, an amplifying transistor 50c (first amplifier), a capacitor 50d, a resistor element 50e (first resistor element), and a resistor element 50f.

The bias supply circuit 201 includes a bias transistor 251 (first bias transistor), a transistor 261 (first diode), a transistor 262 (second diode), a transistor 263 (third diode), a resistor element 271 (second resistor element), a resistor element 272 (fourth resistor element), and a capacitor 281. The transistor 263 and the resistor element 272 may be omitted.

In this embodiment, the amplifying transistor 50c, the bias transistor 251, and the transistors 261, 262, and 263 are, for example, bipolar transistors such as heterojunction bipolar transistors (HBTs). These transistors may be other types of transistors such as metal-oxide-semiconductor field-effect transistors (MOSFETs). In this case, the base, the collector, and the emitter of a transistor may be read as a gate, a drain, and a source, respectively.

The amplifier 50 amplifies an input signal RFin supplied from the input terminal 31 to the input terminal 50a and outputs an output signal RFout from the output terminal 50b.

More particularly, the capacitor 50d in the amplifier 50 has a first end that is connected to the input terminal 31 with the input terminal 50a interposed therebetween and a second end.

The amplifying transistor 50c has a collector that is connected to the output terminal 32 with the output terminal 50b interposed therebetween, a base that is connected to the second end of the capacitor 50d with the resistor element 50f interposed therebetween, and an emitter that is connected to the ground.

The resistor element 50e has a first end that is connected to the bias supply circuit 201 and a second end that is connected to the second end of the capacitor 50d.

The bias supply circuit 201 supplies a bias through the resistor element 50e to the amplifying transistor 50c. More particularly, the bias transistor 251 in the bias supply circuit 201 has a collector that is connected to a battery voltage supply terminal 172, a base that is connected to a node N1 and is supplied with a bias current (first bias), and an emitter that is connected to the first end of the resistor element 50e. The node N1 is connected to a current supply terminal 171 with the resistor element 151 interposed therebetween. A bias voltage may be supplied to the base of the bias transistor 251.

The resistor element 272 has a first end that is connected to the emitter of the bias transistor 251 and a second end.

The transistor 262 has a collector (anode), a base (anode) that is connected to the collector, and an emitter (cathode) that is connected to the ground. Hereinafter, connection between the collector and the base of a transistor may be referred to as diode connection.

Furthermore, a diode-connected transistor may be referred to as a diode.

The transistor 261 is diode-connected and has a collector (anode) and a base (anode) that are connected to the node N1 and an emitter (cathode). The emitter of the transistor 261 is electrically connected to the emitter of the bias transistor 251 and the ground. In this embodiment, the emitter of the transistor 261 is connected to the second end of the resistor element 272 and to the collector and the base of the transistor 262.

The resistor element 271 has a first end that is connected to the node N1 and a second end that is connected to the emitter of the transistor 261.

The capacitor 281 has a first end that is connected to the node N1 and a second end that is connected to the ground.

The transistor 263 is diode-connected and has a collector (anode) and a base (anode) that are connected to the emitter of the bias transistor 251 and an emitter (cathode) that is connected to the ground. Another resistor element may be added between the emitter of the bias transistor 251 and the collector (anode) and the base (anode) of the transistor 263.

An operation of the bias supply circuit 201 will be described below. Current values and voltage values used in the description provided below are illustrative and are not limited to the values illustrated below. As illustrated in FIG. 2, in the low power mode, a small control current is supplied from the current supply terminal 171. In this case, the voltage at the node N1 is lower than a value that is twice the ON voltage of the transistor 261 or 262. Thus, both the transistor 261 and the transistor 262 are not turned on. The transistor 261 and the transistor 262 are turned off and turned on, respectively.

Since the transistor 261 is turned off, the control current does not flow to the transistor 261. That is, the control current flowing from the base to the emitter of the transistor 261 is 0.0 mA. Although the control current does not flow to the transistor 261, since the resistor element 271 is connected between the base and the emitter of the transistor 261, the control current of 0.7 mA flows from the first end toward the second end of the resistor element 271. That is, the control current flows from the node N1 through the resistor element 271 and the transistor 262 to the ground. Hereinafter, a resistor element connected between the collector and the base of a transistor and the emitter of the transistor, such as the resistor element 271, may be referred to a parallel resistor element.

Since the transistor 262 is turned on due to the control current supplied from the node N1 through the resistor element 271, a current of 0.4 mA flows from the base to the emitter of the transistor 262. The emitter voltage of the transistor 261, that is, the base voltage Vn3 of the transistor 262, is 1.25 V. Furthermore, the base voltage Vn1 of the bias transistor 251 is 2.16 V. In other words, the transistor 262 and the resistor element 271 may function as a bias generation circuit.

Since the base voltage Vn1 is lower than the value that is twice the ON voltage of the bias transistor 251 or the transistor 262, the bias transistor 251 is turned off and no current flows from the battery voltage supply terminal 172 to the bias transistor 251.

Even if the bias transistor 251 is turned off, since there is a current path starting from the current supply terminal 171 through the resistor element 151, the node N1, and the resistor elements 271 and 272 to the amplifier 50, a control current of 0.3 mA flows form the second end toward the first end of the resistor element 272. At this time, the emitter voltage Vn2 of the bias transistor 251 is 1.22 V. Thus, the amplifier 50 is turned on and enabled to operate.

As illustrated in FIG. 1, in the high power mode, a large control current is supplied from the current supply terminal 171. In this case, the voltage at the node N1 is approximately twice the ON voltage of the transistor 261 or 262. Thus, both the transistors 261 and 262 are turned on.

At this time, the control current of 1.0 mA flows in each of the resistor element 271 and the transistor 261. The control current of 2.1 mA flows from the base to the emitter of the transistor 262. The base voltage Vn3 of the transistor 262 and the base voltage Vn1 of the bias transistor 251 are 1.3 V and 2.6 V, respectively. That is, the bias to be supplied to the base of the bias transistor 251 can be changed depending on the size of the control current.

Since the voltage that is equal to or more than twice the ON voltage of the bias transistor 251 or the transistor 262 is supplied to the base of the bias transistor 251, the bias transistor 251 is turned on. At this time, a current of 1.5 mA flows from the battery voltage supply terminal 172 to the bias transistor 251. Furthermore, a current of 0.1 mA flows from the first end toward the second end of the resistor element 272. The emitter voltage Vn2 of the bias transistor 251 becomes 1.31 V, and the amplifier 50 can be caused to operate using a large bias.

### (Effects)

FIG. 3 is a diagram illustrating an example of changes in a DC component Vndc2 of the emitter voltage Vn2 of the bias transistor 251 in the bias supply circuit 201 according to this embodiment and a DC component Vrdc2 of the emitter voltage of the bias transistor 912 in the bias supply circuit 910 according to the comparative example with respect to output power. In FIG. 3, the horizontal axis represents electric power output from the output terminal 32 and the vertical axis represents voltage.

As illustrated in FIGS. 1 to 3, since the node N1 is connected to the ground with the capacitor 281 interposed therebetween, the base of the bias transistor 251 that is connected to the node N1 is substantially short-circuited to the ground in terms of an RF signal.

Part of the input signal RFin input from the input terminal 31 flows through the resistor element 50e, the emitter and the base of the bias transistor 251, and the node N1 to the ground. At this time, the input signal RFin flowing in the bias transistor 251 is half-wave rectified due to diode characteristics between the base and the emitter of the bias transistor 251. Thus, the DC component Vndc2 of the emitter voltage Vn2 of the bias transistor 251 increases as the level of the input signal RFin increases.

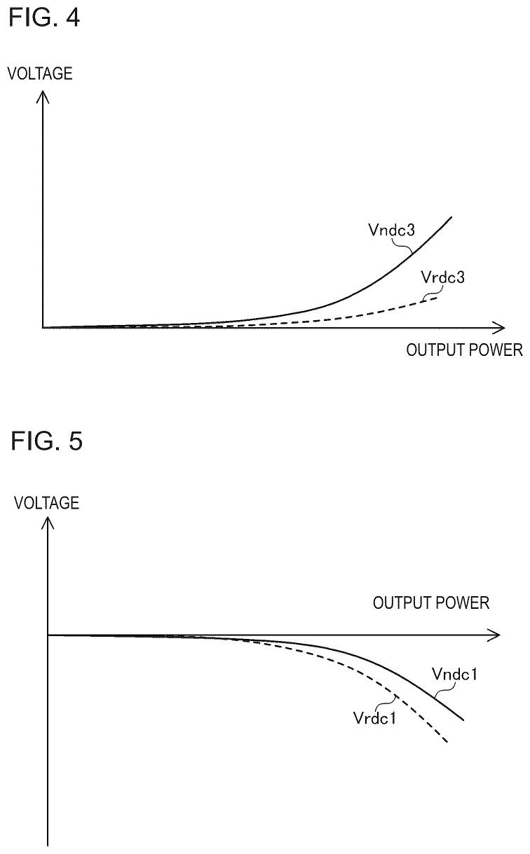

FIG. 4 is a diagram illustrating an example of changes in a DC component Vndc3 of the base voltage Vn3 of the transistor (diode) 262 in the bias supply circuit 201 according to this embodiment and a DC component Vrdc3 of the base voltage of the transistor (diode) 926 in the bias supply circuit 910 according to the comparative example with respect to output power. FIG. 4 can be read in the same manner as in FIG. 3.

As illustrated in FIGS. 1, 2, and 4, in the bias supply circuit 201, part of the input signal RFin input from the input terminal 31 also flows through the resistor element 50e, the resistor element 272, the transistor 261 or the resistor element 271, and the node N1 to the ground. In the bias supply circuit 201, unlike the bias supply circuit 910 according to the comparative example (see FIG. 13), the transistor 261 is connected between the node N1 and the collector and the base of the transistor 262. Thus, the input signal RFin flowing in the transistor 261 is half-wave rectified due to diode characteristics between the base and the emitter of the transistor 261.

Accordingly, over a range from a sufficiently small output power (for example, −20 dBm) to a large output power, a DC component of the emitter voltage of the transistor 261, that is, the DC component Vndc3 of the base voltage Vn3 of the transistor 262, can be increased to be larger than the DC component Vrdc3 of the base voltage of the transistor 926 (see FIG. 13).

FIG. 5 is a diagram illustrating an example of changes in a DC component Vndc1 of the base voltage Vn1 of the bias transistor 251 in the bias supply circuit 201 according to this embodiment and a DC component Vrdc1 of the base voltage of the bias transistor 912 in the bias supply circuit 910 according to the comparative example with respect to output power. FIG. 5 can be read in the same manner as in FIG. 3.

As illustrated in FIG. 5, over a range from a sufficiently small output power (for example, −20 dBm) to a large output power, the DC component Vndc3 can be increased to be larger than the DC component Vrdc3 (see FIG. 4). Thus, the DC component Vndc1 of the base voltage Vn1 of the bias transistor 251 can also be increased to be larger than the DC component Vrdc1 of the base voltage of the transistor 912 (see FIG. 13).

In the case where the DC component Vndc1 of the base voltage Vn1 of the bias transistor 251 is high, the DC component Vndc2 of the emitter voltage Vn2 of the bias transistor 251 is also high, as illustrated in FIG. 3.

Thus, in the case of the same output power, the DC component Vndc2 of the emitter voltage Vn2 of the bias transistor 251 can be set to be higher than the DC component Vrdc2 of the emitter voltage of the bias transistor 912. Thus, since the base current of the amplifying transistor 50c can be supplied sufficiently, the output power of the power amplifier circuit 101 can be larger than the output power of the bias supply circuit 910 according to the comparative example illustrated in FIG. 13.

### Second Embodiment

A power amplifier circuit 102 according to a second embodiment will be described. In the second and subsequent embodiments, description of features that are in common with the first embodiment will be omitted and only different features will be described. In particular, similar operational effects achieved by similar configurations will not be described in each embodiment.

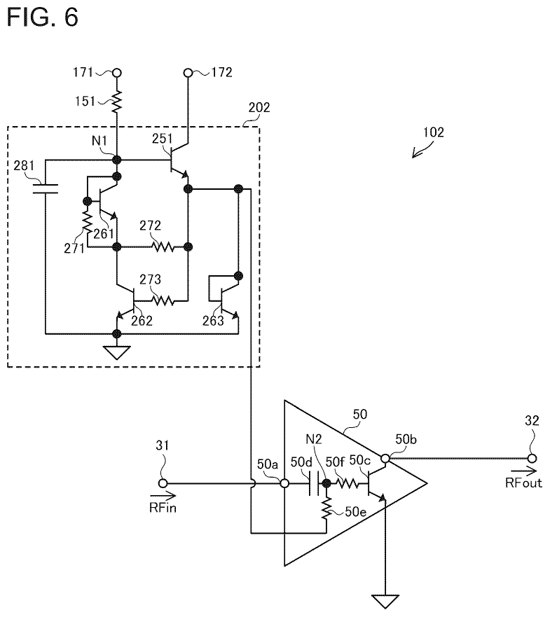

FIG. 6 is a circuit diagram of the power amplifier circuit 102. As illustrated in FIG. 6, the power amplifier circuit 102 according to the second embodiment is different from the power amplifier circuit 101 according to the first embodiment in that a negative feedback circuit is formed in a bias circuit.

Unlike the power amplifier circuit 101 illustrated in FIG. 1, the power amplifier circuit 102 includes a bias supply circuit 202 instead of the bias supply circuit 201. Unlike the bias supply circuit 201 illustrated in FIG. 1, the bias supply circuit 202 further includes a resistor element 273 (third resistor element).

In the bias supply circuit 202, the transistor 262 has a collector that is connected to the emitter of the transistor 261, a base, and an emitter that is connected to the ground. That is, in the bias supply circuit 202, the transistor 262 does not function as a diode but functions as a transistor.

The resistor element 273 has a first end that is connected to the emitter of the bias transistor 251 and a second end that is connected to the base of the transistor 262.

Next, an operation of the power amplifier circuit 102 will be described. In the low power mode, as in the bias supply circuit 201 illustrated in FIG. 2, the bias transistor 251 and the transistor 261 are turned off and the transistor 262 is turned on.

At this time, the control current flows in a current path starting from the current supply terminal 171 through the resistor element 151, the node N1, and the resistor elements 271 and 272 to the amplifier 50. Thus, the amplifier 50 is turned on and enabled to operate.

In the high power mode, the bias transistor 251 and the transistor 261 are turned on. Thus, a feedback path starting from the emitter of the bias transistor 251 through the resistor element 273, the base and the collector of the transistor 262, the emitter and the base of the transistor 261, the node N1, and the base of the bias transistor 251 to the emitter of the bias transistor 251 is formed.

When part of the input signal RFin input from the input terminal 31 is transmitted through the feedback path, the phase of the input signal RFin is shifted by approximately 180 degrees between the collector of the transistor 262 and the base of the transistor 262.

Thus, the input signal RFin whose phase is shifted by approximately 180 degrees while being transmitted through the feedback path is returned to the emitter of the bias transistor 251. That is, in the bias supply circuit 202, a negative feedback circuit in which the input signal RFin whose phase has been shifted by approximately 180 degrees is returned to the emitter of the bias transistor 251 is formed. Thus, the impedance when the bias supply circuit 202 is seen from a node N2 between the capacitor 50d and the resistor element 50f (hereinafter, may be referred to as an output impedance) can be reduced.

For example, when the amplitude of the input signal RFin is modulated, the input signal RFin contains a component of a carrier wave caused to vibrate by RF and a component of a modulation wave forming an envelope. In the power amplifier circuit 102, since the output impedance of the bias supply circuit 202 can be reduced, the linearity with respect to a modulation wave can be improved.

### Third Embodiment

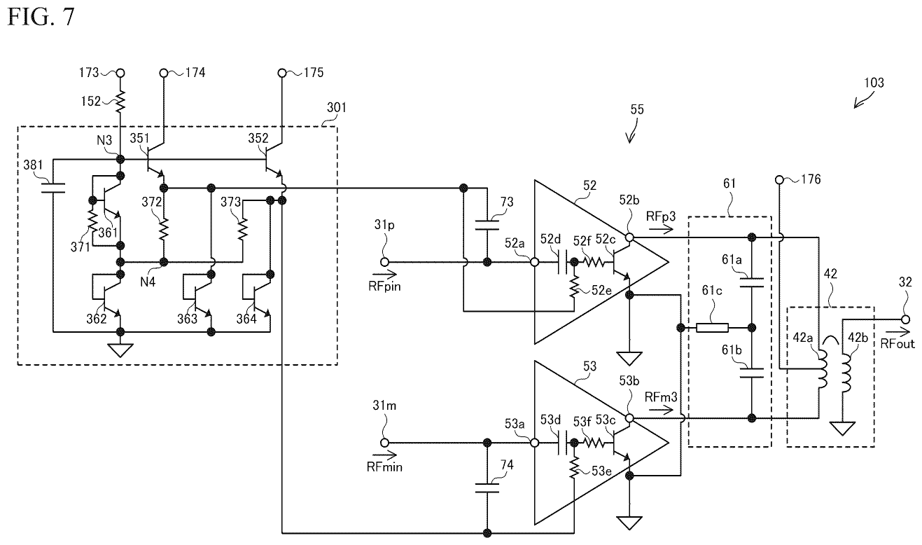

A power amplifier circuit 103 according to a third embodiment will be described. FIG. 7 is a circuit diagram of the power amplifier circuit 103. As illustrated in FIG. 7, the power amplifier circuit 103 according to the third embodiment is different from the power amplifier circuit 101 according to the first embodiment in that the power amplifier circuit 103 amplifies differential signals.

Unlike the power amplifier circuit 101 illustrated in FIG. 1, the power amplifier circuit 103 includes a differential pair 55 and a bias supply circuit 301 instead of the amplifier 50 and the bias supply circuit 201, respectively, and further includes a balun 42, a matching circuit 61, capacitors 73 and 74, and a resistor element 152.

The bias supply circuit 301 includes a bias transistor 351 (first bias transistor), a bias transistor 352 (second bias transistor), a transistor 361 (first diode), a transistor 362 (second diode), and transistors 363 and 364 (third diodes), a resistor element 371 (second resistor element), a resistor element 372 (fourth resistor element), a resistor element 373 (sixth resistor element), and a capacitor 381.

The differential pair 55 includes amplifiers 52 and 53. The amplifier 52 includes an input terminal 52a, an output terminal 52b, an amplifying transistor 52c (first amplifier), a capacitor 52d, and resistor elements 52e and 52f. The amplifier 53 includes an input terminal 53a, an output terminal 53b, an amplifying transistor 53c (second amplifier), a capacitor 53d, a resistor element 53e (fifth resistor element), and a resistor element 53f. Configurations of the amplifiers 52 and 53 are similar to the configuration of the amplifier 50.

The balun 42 includes inductors 42a and 42b. The matching circuit 61 includes capacitors 61a and 61b and a microstrip line 61c.

An input signal RFpin, which is one of balance signals, and an input signal RFmin, which is the other one of the balance signals, are input to input terminals 31p and 31m, respectively. The phase of the input signal RFpin is different from the phase of the input signal RFmin by approximately 180 degrees. Due to unbalanced wire length in the circuit or other factors, the phase difference may be largely different from 180 degrees.

The amplifier 52 amplifies the input signal RFpin supplied from the input terminal 31p and outputs an amplification signal RFp3. More particularly, the capacitor 52d in the amplifier 52 has a first end that is connected to the input terminal 31p with the input terminal 52a interposed therebetween and a second end.

The amplifying transistor 52c has a collector that is connected to the output terminal 52b, a base that is connected to the second end of the capacitor 52d with the resistor element 52f interposed therebetween, and an emitter that is connected to the ground.

The resistor element 52e has a first end that is connected to the bias supply circuit 301 and a second end that is connected to the second end of the capacitor 52d. The capacitor 73 has a first end that is connected to the first end of the resistor element 52e and a second end that is connected to the input terminal 52a of the amplifier 52.

The amplifier 53 amplifies the input signal RFmin supplied from the input terminal 31m and outputs an amplification signal RFm3. More particularly, the capacitor 53d in the amplifier 53 has a first end that is connected to the input terminal 31m with the input terminal 53a interposed therebetween and a second end.

The amplifying transistor 53c has a collector that is connected to the output terminal 53b, a base that is connected to the second end of the capacitor 53d with the resistor element 53f interposed therebetween, and an emitter that is connected to the ground.

The resistor element 53e has a first end that is connected to the bias supply circuit 301 and a second end that is connected to the second end of the capacitor 53d. The capacitor 74 has a first end that is connected to the first end of the resistor element 53e and a second end that is connected to the input terminal 53a of the amplifier 53.

The balun 42 converts the amplification signals RFp3 and RFm3 that are output from the amplifiers 52 and 53, respectively, into an output signal RFout, which is a single-end signal.

More particularly, the inductor 42a in the balun 42 has a first end that is connected to the output terminal 52b of the amplifier 52, an intermediate tap that is connected to a power supply voltage supply terminal 176, and a second end that is connected to the output terminal 53b of the amplifier 53.

The inductor 42b has a first end that is connected to the output terminal 32 and a second end that is connected to the ground. The inductor 42b is electromagnetically coupled to the inductor 42a and outputs, from the first end, an output signal RFout, which is an unbalanced signal, to the output terminal 32.

The matching circuit 61 is provided between the differential pair 55 and the balun 42 and matches impedance between the differential pair 55 and the balun 42. More particularly, the capacitor 61a in the matching circuit 61 has a first end that is connected to the output terminal 52b of the amplifier 52 and a second end. The capacitor 61b has a first end that is connected to the output terminal 53b of the amplifier 53 and a second end that is connected to the second end of the capacitor 61a. The microstrip line 61c has a first end that is connected to the second end of the capacitor 61a and a second end that is connected to the ground.

The bias supply circuit 301 supplies a bias to the amplifying transistors 52c and 53c through the resistor elements 52e and 53e, respectively. More particularly, the bias transistor 351 in the bias supply circuit 301 has a collector that is connected to a battery voltage supply terminal 174, a base that is connected to a node N3 and is supplied with a bias current (first bias), and an emitter that is connected to the first end of the resistor element 52e.

The bias transistor 352 has a collector that is connected to a battery voltage supply terminal 175, a base that is connected to the base of the bias transistor 351, and an emitter that is connected to the first end of the resistor element 53e.

The node N3 is connected to the current supply terminal 173 with the resistor element 152 interposed therebetween. A bias voltage may be supplied to the base of the bias transistor 351 and the base of the bias transistor 352.

Each of the transistors 362, 363, and 364 is diode-connected and has a collector (anode), a base (anode), and an emitter (cathode) that is connected to the ground.

The resistor element 372 has a first end that is connected to the emitter of the bias transistor 351 and the collector and the base of the transistor 363 and a second end that is connected to a node N4. The resistor element 373 has a first end that is connected to the emitter of the bias transistor 352 and the collector and the base of the transistor 364 and a second end that is connected to the node N4.

The transistor 361 is diode-connected and has a collector (anode) and a base (anode) that are connected to the node N3, and an emitter(cathode) that is connected to the node N4 and the collector and the base of the transistor 362.

The resistor element 371 is a parallel resistor element and has a first end that is connected to the node N3 and a second end that is connected to the emitter of the transistor 361. The capacitor 381 has a first end that is connected to the node N3 and a second end that is connected to the ground.

With the configuration described above, the circuit scale can be reduced compared to a configuration in which the bias supply circuit 201 is provided for each of the amplifiers 52 and 53.

Furthermore, in the low power mode, the phase of the input signal RFpin that flows from the input terminal 31p through the resistor element 372 to the node N4 and the phase of the input signal RFmin that flows from the input terminal 31m through the resistor element 373 to the node N4 are different by approximately 180 degrees. Thus, the node N4 is in an imaginary short-circuit state. That is, the value of the output impedance of the bias supply circuit 301 is equal to the resistance value of the resistor element 372 or the resistance value of the resistor element 373 at an odd-order frequency of an input signal frequency.

### Fourth Embodiment

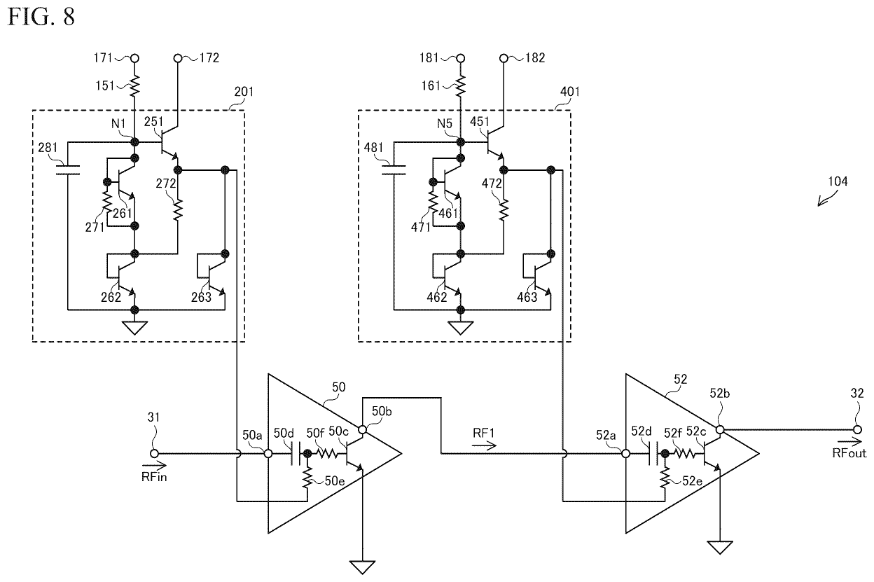

A power amplifier circuit 104 according to a fourth embodiment will be described. FIG. 8 is a circuit diagram of the power amplifier circuit 104. As illustrated in FIG. 8, the power amplifier circuit 104 according to the fourth embodiment is different from the power amplifier circuit 101 according to the first embodiment in that the power amplifier circuit 104 is a two-stage amplifier circuit.

Unlike the power amplifier circuit 101 illustrated in FIG. 1, the power amplifier circuit 104 further includes an amplifier 52, a bias supply circuit 401, and a resistor element 161.

The bias supply circuit 401 includes a bias transistor 451 (third bias transistor), a transistor 461 (fourth diode), a transistor 462 (second diode), a transistor 463 (third diode), a resistor element 471 (eighth resistor element), a resistor element 472 (fourth resistor element), and a capacitor 481. The bias supply circuit 401 is similar to the bias supply circuit 201 illustrated in FIG. 1.

The amplifier 52 is similar to the amplifier 52 illustrated in FIG. 7. The amplifier 52 is cascade-connected to the amplifier 50. In this embodiment, the amplifier 50 is a driver-stage amplifier. The amplifier 52 is a power-stage amplifier that is provided at the stage subsequent to the amplifier 50. The amplifier 50 amplifies an input signal RFin supplied from the input terminal 31 and outputs an amplification signal RF1. The amplifier 52 amplifies an amplification signal RF1 output from the amplifier 50 and outputs an output signal RFout to the output terminal 32.

The bias supply circuit 401 supplies a bias through a resistor element 52e (seventh resistor element) to an amplifying transistor 52c (third amplifier). More particularly, the bias transistor 451 in the bias supply circuit 401 has a collector that is connected to a battery voltage supply terminal 182, a base that is connected to a node N5 and is supplied with a bias current (second bias), and an emitter that is connected to a first end of the resistor element 52e. The node N5 is connected to a current supply terminal 181 with the resistor element 161 interposed therebetween. A bias voltage may be supplied to the base of the bias transistor 451.

Each of the transistors 462 and 463 is diode-connected and has a collector (anode), a base (anode), and an emitter (cathode) that is connected to the ground.

The resistor element 472 has a first end that is connected to the emitter of the bias transistor 451 and the collector and the base of the transistor 463 and a second end.

The transistor 461 is diode-connected and has a collector (anode) and a base (anode) that are connected to the node N5 and an emitter (cathode). The emitter of the transistor 461 is electrically connected to the emitter of the bias transistor 451 and the ground. In this embodiment, the emitter of the transistor 461 is connected to the second end of the resistor element 472 and the collector and the base of the transistor 462.

The resistor element 471 is a parallel resistor element and has a first end that is connected to the node N5 and a second end that is connected to the emitter of the transistor 461. The capacitor 481 has a first end that is connected to the node N5 and a second end that is connected to the ground.

### Fifth Embodiment

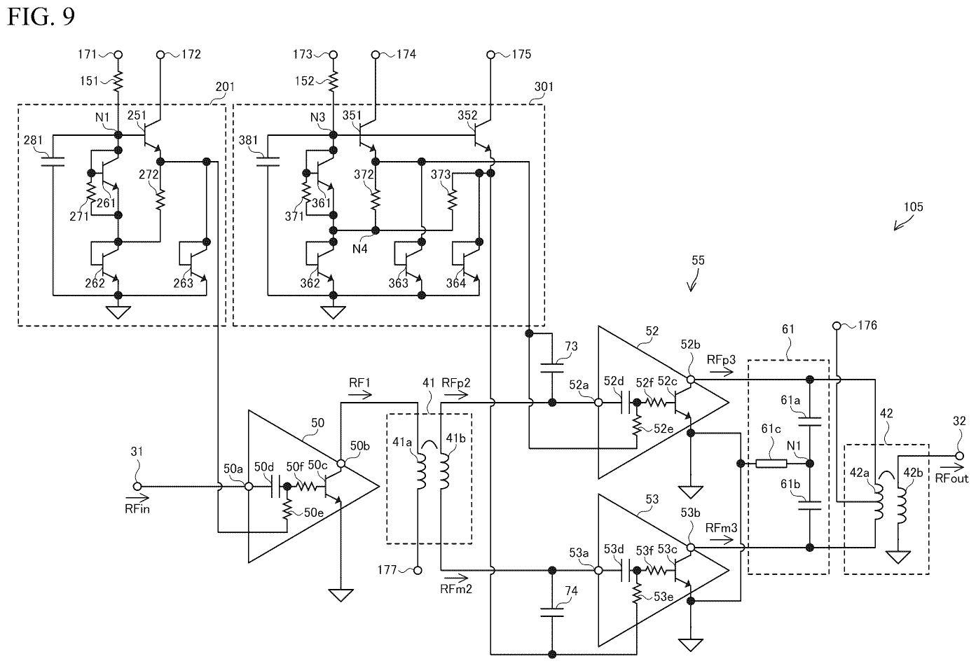

A power amplifier circuit 105 according to a fifth embodiment will be described. FIG. 9 is a circuit diagram of the power amplifier circuit 105. As illustrated in FIG. 9, the power amplifier circuit 105 according to the fifth embodiment is different from the power amplifier circuit 103 according to the third embodiment in that the power amplifier circuit 105 is a two-stage amplifier circuit.

Unlike the power amplifier circuit 103 illustrated in FIG. 7, the power amplifier circuit 105 further includes a balun 41, an amplifier 50, a resistor element 151, and a bias supply circuit 201. The balun 41 includes inductors 41a and 41b. The amplifier 50 and the bias supply circuit 201 are similar to the amplifier 50 and the bias supply circuit 201 illustrated in FIG. 1, respectively.

The amplifier 50 is a driver-stage amplifier. The amplifier 50 amplifies an input signal RFpin supplied through the input terminal 31 and outputs an amplification signal RF1.

The balun 41 converts a single-end signal, that is, an amplification signal RF1, output from the amplifier 50 into amplification signals RFp2 and RFm2, which are differential signals, and matches impedance between the amplifier 50 and the differential pair 55.

More particularly, the inductor 41a in the balun 41 has a first end that is connected to the output terminal 50b of the amplifier 50 and a second end that is connected to a power supply voltage supply terminal 177.

The inductor 41b has a first end that is connected to the input terminal 52a of the amplifier 52 and a second end that is connected to the input terminal 53a of the amplifier 53, and the inductor 41b is electromagnetically coupled to the inductor 41a.

The amplifiers 52 and 53 in the differential pair 55 are power-stage amplifiers. The amplifier 52 amplifies an amplification signal RFp2 output from the first end of the inductor 41b in the balun 41 and outputs an amplification signal RFp3. The amplifier 53 amplifies an amplification signal RFm2 output from the second end of the inductor 41b in the balun 41 and outputs an amplification signal RFm3.

Although the configurations of the bias supply circuits 201 and 202 in which the transistor 263 is provided between the emitter of the bias transistor 251 and the ground have been described above, the bias supply circuits 201 and 202 are not necessarily configured as described above. In the bias supply circuits 201 and 202, the transistor 263 is not necessarily provided and the emitter of the bias transistor 251 may be directly connected to the ground. The same applies to the bias supply circuit 401.

Furthermore, although the configurations of the bias supply circuits 201 and 202 in which the collector and the base of the transistor 263 are directly connected to the emitter of the bias transistor 251, the first end of the resistor element 272, and the first end of the resistor element 50e have been described above, the bias supply circuits 201 and 202 are not necessarily configured as described above. The collector and the base of the transistor 263 may be connected to the emitter of the bias transistor 251 with a resistor element interposed therebetween, the first end of the resistor element 272, and the first end of the resistor element 50e. The same applies to the bias supply circuit 401.

Furthermore, although the configuration of the bias supply circuit 301 in which the transistors 363 and 364 are provided between the emitter of the bias transistor 351 and the ground and between the emitter of the bias transistor 352 and the ground, respectively, has been described above, the bias supply circuit 301 is not necessarily configured as described above. In the bias supply circuit 301, the transistor 363 is not necessarily provided and the emitter of the bias transistor 351 may be directly connected to the ground. Furthermore, the transistor 364 is not necessarily provided and the emitter of the bias transistor 352 may be directly connected to the ground.

Furthermore, although the configuration of the bias supply circuit 301 in which the collector and the base of the transistor 363 are directly connected to the emitter of the bias transistor 351, the first end of the resistor element 372, and the first end of the resistor element 52e has been described above, the bias supply circuit 301 is not necessarily configured as described above. The collector and the base of the transistor 363 may be connected to the emitter of the bias transistor 351 with a resistor element interposed therebetween, the first end of the resistor element 372, and the first end of the resistor element 52e. As with the collector and the base of the transistor 363, the collector and the base of the transistor 364 may also be connected to the emitter of the bias transistor 352 with a resistor element interposed therebetween, the first end of the resistor element 373, and the first end of the resistor element 53e.

### Sixth Embodiment

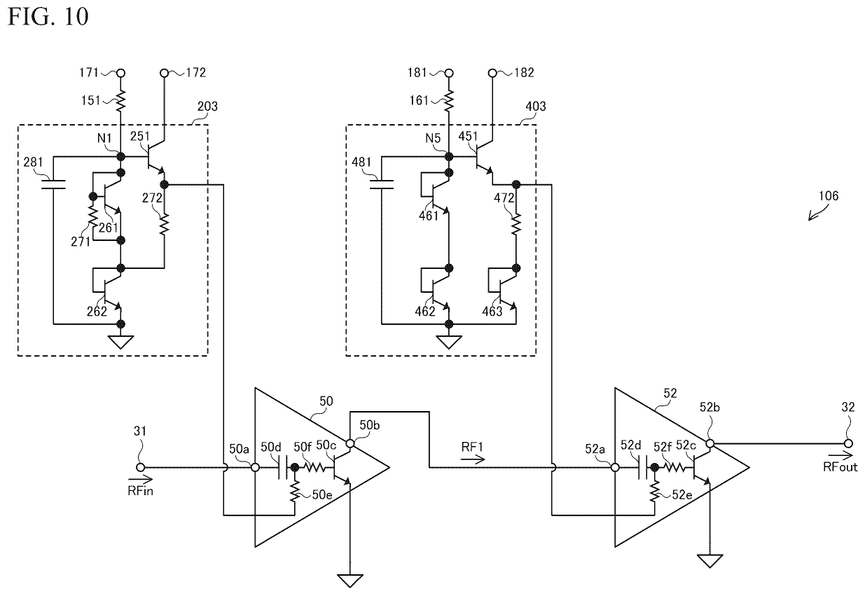

A power amplifier circuit 106 according to a sixth embodiment will be described. FIG. 10 is a circuit diagram of the power amplifier circuit 106. As illustrated in FIG. 10, the power amplifier circuit 106 according to the sixth embodiment is different from the power amplifier circuit 104 according to the fourth embodiment in that a bias supply circuit 403 that supplies a bias to the power-stage amplifier 52 does not include a parallel resistor element.

Unlike the power amplifier circuit 104 illustrated in FIG. 8, the power amplifier circuit 106 includes bias supply circuits 203 and 403 instead of the bias supply circuits 201 and 401, respectively.

Unlike the bias supply circuit 201 illustrated in FIG. 8, the bias supply circuit 203 does not include the transistor 263.

Unlike the bias supply circuit 401 illustrated in FIG. 8, the bias supply circuit 403 does not include the resistor element 471, which is a parallel resistor element. The resistor element 472 has a first end that is connected to the emitter of the bias transistor 451 and a second end that is connected to the collector and the base of the transistor 463.

As described above, in a power amplifier circuit including amplifiers of two or more stages, a bias supply circuit that supplies a bias to at least one of the amplifiers of two or more stages does not necessarily include a parallel resistor element. Thus, sensitivity with respect to variations in the control current in the current supply terminals 171 and 181 is prevented from becoming too high, and a stable bias supply can be achieved. Furthermore, in the configuration in this embodiment, since the bias supply circuit 203 that supplies a bias to the amplifier 50 includes a parallel resistor element, the control current can be reduced, and a reduction in the maximum power of the amplifier can be suppressed.

The bias supply circuit 403 does not necessarily include at least one of the transistor 463 and the resistor element 472.

### Seventh Embodiment

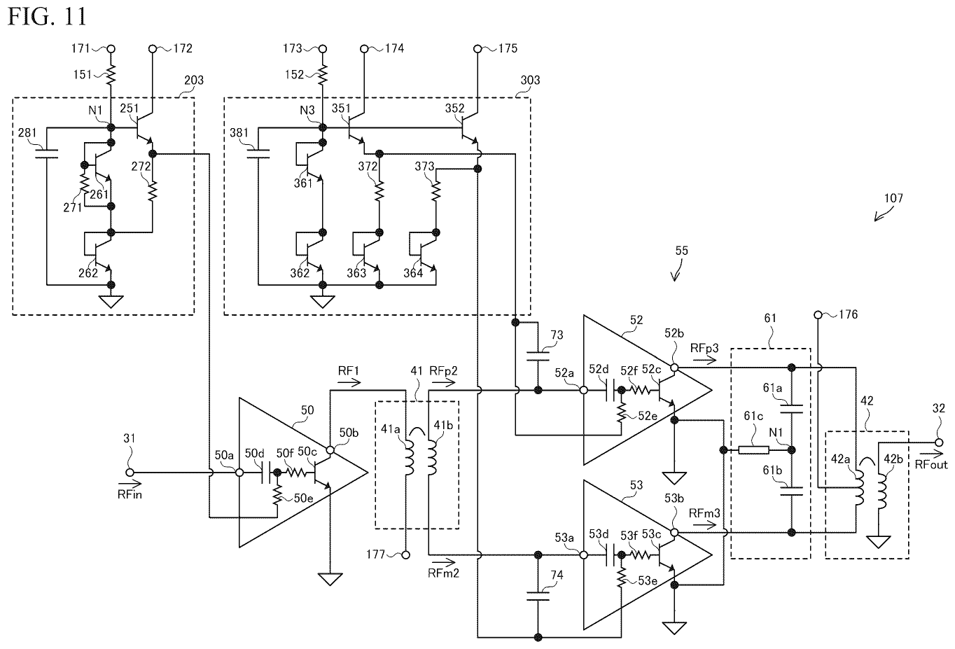

A power amplifier circuit 107 according to a seventh embodiment will be described. FIG. 11 is a circuit diagram of the power amplifier circuit 107. As illustrated in FIG. 11, the power amplifier circuit 107 according to the seventh embodiment is different from the power amplifier circuit 105 according to the fifth embodiment in that a bias supply circuit 303 that supplies a bias to the power-stage differential pair 55 does not include a parallel resistor element.

Unlike the power amplifier circuit 105 illustrated in FIG. 9, the power amplifier circuit 107 includes bias supply circuits 203 and 303 instead of the bias supply circuits 201 and 301, respectively.

Unlike the bias supply circuit 201 illustrated in FIG. 9, the bias supply circuit 203 does not include the transistor 263.

Unlike the bias supply circuit 301 illustrated in FIG. 9, the bias supply circuit 303 does not include the resistor element 371, which is a parallel resistor element. The resistor element 372 has a first end that is connected to the emitter of the bias transistor 351 and a second end that is connected to the collector and the base of the transistor 363.

The resistor element 373 has a first end that is connected to the emitter of the bias transistor 352 and a second end that is connected to the collector and the base of the transistor 364.

As described above, in a power amplifier circuit that includes amplifiers of two or more stages including a differential pair, a parallel resistor element may be removed from a bias supply circuit that supplies a bias to the differential pair. Thus, sensitivity with respect to variations in the control current in the current supply terminals 171 and 173 is prevented from becoming too high, and a stable bias supply can be achieved. Furthermore, in the configuration in this embodiment, since the bias supply circuit 203 that supplies a bias to the amplifier 50 includes a parallel resistor element, the control current can be reduced, and a reduction in the maximum power of the amplifier can be suppressed.

The bias supply circuit 303 does not necessarily include at least one of the transistors 363 and 364 and does not necessarily include at least one of the resistor elements 372 and 373.

Illustrative embodiments of the present disclosure have been described above. In the bias supply circuits 201 and 202, the bias transistor 251 has a base that is supplied with a first bias and an emitter that supplies a bias through the resistor element 50e to the amplifying transistor 50c.

The transistor 261 is diode-connected and has a collector and a base that are connected to the base of the bias transistor 251 and an emitter that is electrically connected to the emitter of the bias transistor 251. The resistor element 271 has a first end that is connected to the collector and the base of the transistor 261 and a second end that is connected to the emitter of the transistor 261. The capacitor 281 has a first end that is connected to the collector and the base of the transistor 261 and a second end that is connected to the ground. The emitter of the transistor 261 is electrically connected to the ground.

With the configuration described above, by causing the control current to flow from the collector and the base of the transistor 261 to the ground, the transistor 261 and the resistor element 271 function as a bias generation circuit, and the first bias to be supplied to the base of the bias transistor 251 can be generated at the collector and the base of the transistor 261. In addition, since a single path through which the control current flows is formed, the amplifying transistor 50c can be driven using a small control current. Furthermore, with the configuration in which the diode-connected transistor 261 is connected between the base of the bias transistor 251 and the ground, part of the input signal RFin can be half-wave rectified due to the diode characteristics between the base and the emitter of the transistor 261 in the high power mode. Thus, the DC component Vndc3 of the emitter voltage of the transistor 261 can be increased, according to the level of the input signal RFin, to be larger than the DC component Vrdc3 of the base voltage of the transistor 926 (see FIG. 13). In addition, the DC component Vndc1 of the base voltage Vn1 and the DC component Vndc2 of the emitter voltage Vn2 of the bias transistor 251 can also be increased to be larger than the DC component Vrdc1 of the base voltage and the DC component Vrdc2 of the emitter voltage of the transistor 912 (see FIG. 13), respectively. Thus, the maximum power of the amplifying transistor 50c can be increased to be larger than the maximum power of the amplifying transistor 954 (see FIG. 13). Therefore, the control current can be reduced, and a reduction in the maximum power of the amplifier can be suppressed.

Furthermore, in the bias supply circuit 201, the transistor 262 is diode-connected and has a collector, a base, and an emitter that is connected to the ground. The emitter of the transistor 261 is connected to the collector and the base of the transistor 262.

With the configuration described above, the emitter voltage of the transistor 261 can be easily stabilized at or near the ON voltage of the transistor 262.

Furthermore, in the bias supply circuit 202, the transistor 262 has a collector, a base, and an emitter that is connected to the ground. The resistor element 273 is connected between the emitter of the bias transistor 251 and the base of the transistor 262. The emitter of the transistor 261 is connected to the collector of the transistor 262.

With the configuration described above, a negative feedback circuit that starts from the emitter of the bias transistor 251 through the resistor element 273, the base and the collector of the transistor 262, the emitter and the base of the transistor 261, and the base of the bias transistor 251 to the emitter of the bias transistor 251 can be formed. Thus, since the output impedance of the bias supply circuit 202 can be reduced, the linearity with respect to a modulation wave can be improved.

Furthermore, in the bias supply circuits 201 and 202, the transistor 263 is diode-connected and has a collector and a base that are connected to the emitter of the bias transistor 251 and an emitter that is connected to the ground.

With the configuration described above, the emitter voltage Vn2 of the bias transistor 251 can be easily stabilized at or near the ON voltage of the transistor 263.

Furthermore, in the bias supply circuits 201 and 202, the emitter of the transistor 261 is connected to the emitter of the bias transistor 251 with the resistor element 272 interposed therebetween.

With the configuration described above, the value of the output impedance of the bias supply circuits 201 and 202 in the low power mode can be adjusted according to the resistance value of the resistor element 272.

Furthermore, in the bias supply circuit 301, the bias transistor 351 has a base that is supplied with the first bias and an emitter that supplies a bias through the resistor element 52e to the amplifying transistor 52c. The transistor 361 is diode-connected and has a collector and a base that are connected to the base of the bias transistor 351 and an emitter that is connected to the emitter of the bias transistor 351 with the resistor element 372 interposed therebetween. The resistor element 371 has a first end that is connected to the collector and the base of the transistor 361 and a second end that is connected to the emitter of the transistor 361. The capacitor 381 has a first end that is connected to the collector and the base of the transistor 361 and a second end that is connected to the ground. The bias transistor 352 has a base that is connected to the base of the bias transistor 351 and an emitter that supplies a bias through the resistor element 53e to the amplifying transistor 53c, the amplifying transistor 52c and the amplifying transistor 53c forming the differential pair 55. The emitter of the transistor 361 is connected to the emitter of the bias transistor 352 with the resistor element 373 interposed therebetween.

With the configuration described above, the circuit scale can be reduced compared to a configuration in which the bias supply circuit 201 is provided for each of the amplifying transistors 52c and 53c in the differential pair 55. Furthermore, since the emitter of the transistor 361 is in an imaginary short-circuit state, the resistance value of the resistor element 372 and the resistance value of the resistor element 373 are set appropriately so that the value of the output impedance of the bias supply circuit 301 in the low power mode can be adjusted.

Furthermore, in the bias supply circuit 401, the bias transistor 451 has a base that is supplied with a second bias and an emitter that supplies a bias through the resistor element 52e to the amplifying transistor 52c that is cascade-connected to the amplifying transistor 50c. The transistor 461 is diode-connected and has a collector and a base that are connected to the base of the bias transistor 451 and an emitter that is electrically connected to the emitter of the bias transistor 451. The resistor element 471 has a first end that is connected to the collector and the base of the transistor 461 and a second end that is connected to the emitter of the transistor 461. The capacitor 481 has a first end that is connected to the collector and the base of the transistor 461 and a second end that is connected to the ground. The emitter of the transistor 461 is electrically connected to the ground.

With the configuration described above, also in the case of the two-stage amplifier circuit, the control current in the bias supply circuits 201 and 401 can be reduced, and a reduction in the maximum power of the amplifying transistor 50c and the amplifying transistor 52c can be suppressed.

Each of the embodiments described above is intended to facilitate understanding of the present disclosure and is not to be interpreted as limiting the present disclosure. The present disclosure can be modified or improved without necessarily departing from the gist of the disclosure, and the present disclosure encompasses equivalents thereof. That is, design changes appropriately added to each of the embodiments by those skilled in the art are also included in the scope of the present disclosure as long as the design changes include features of the present disclosure. For example, elements included in each of the embodiments and arrangement, materials, conditions, shapes, and sizes of the elements are not limited to those illustrated above and can be modified appropriately. Furthermore, each of the embodiments is illustrative. Obviously, configurations described in different embodiments can be partially replaced or combined with one another, and the configurations that are partially replaced or combined are also included in the scope of the present disclosure as long as the configurations include features of the present disclosure.

### REFERENCE SIGNS LIST

31, 31p, 31m . . . input terminal
32 . . . output terminal
41, 42 . . . balun
50, 52, 53 . . . amplifier
50c, 52c, 53c . . . amplifying transistor
50e, 52e, 53e . . . resistor element
55 . . . differential pair
61 . . . matching circuit
73, 74 . . . capacitor
101, 102, 103, 104, 105, 106, 107 . . . power amplifier circuit
151, 152, 161 . . . resistor element
201, 202, 203 . . . bias supply circuit
251 . . . bias transistor
261, 262, 263 . . . transistor
271, 272, 273 . . . resistor element
281 . . . capacitor
301, 303 . . . bias supply circuit
351, 352 . . . bias transistor
361, 362, 363, 364 . . . transistor
371, 372, 373 . . . resistor element
381 . . . capacitor
401, 403 . . . bias supply circuit
451 . . . bias transistor
461, 462, 463 . . . transistor
471, 472 . . . resistor element
481 . . . capacitor

1. A bias circuit comprising:
a first bias transistor that has a base or a gate that is supplied with a first bias, and an emitter or a source that is configured to supply a bias to a first amplifier through a first resistor circuit element;
a first diode that has an anode that is connected to the base or the gate of the first bias transistor, and a cathode that is electrically connected to the emitter or the source of the first bias transistor;
a second resistor circuit element that has a first end that is connected to the anode of the first diode, and a second end that is connected to the cathode of the first diode; and
a capacitor that has a first end that is connected to the anode of the first diode, and a second end that is connected to ground,
wherein the cathode of the first diode is electrically connected to ground.

2. The bias circuit according to claim 1, further comprising:
a second diode that has an anode, and a cathode that is connected to ground,
wherein the cathode of the first diode is connected to the anode of the second diode.

3. The bias circuit according to claim 1, further comprising:
a transistor that has a collector or a drain, a base or a gate, and an emitter or a source that is connected to ground; and
a third resistor circuit element that is connected between the emitter or the source of the first bias transistor and the base or the gate of the transistor,
wherein the cathode of the first diode is connected to the collector or the drain of the transistor.

4. The bias circuit according to claim 1, further comprising:
a third diode that has an anode that is connected to the emitter or the source of the first bias transistor, and a cathode that is connected to ground.

5. The bias circuit according to claim 1,
wherein the cathode of the first diode is connected to the emitter or the source of the first bias transistor, and
wherein a fourth resistor circuit element is connected between the cathode of the first diode and the emitter or the source of the first bias transistor.

6. The bias circuit according to claim 5, further comprising:
a second bias transistor that has a base or a gate that is connected to the base or the gate of the first bias transistor, and an emitter or a source that is configured to supply a bias to a second amplifier through a fifth resistor circuit element,
wherein the first amplifier and the second amplifier form a differential pair,
wherein the cathode of the first diode is connected to the emitter or the source of the second bias transistor, and
wherein a sixth resistor circuit element is connected between the cathode of the first diode and the emitter or the source of the second bias transistor.

7. The bias circuit according to claim 1, further comprising:
a third bias transistor that has a base or a gate that is supplied with a second bias, and an emitter or a source that is configured to supply a bias to a third amplifier through a seventh resistor circuit element, the third amplifier being cascade-connected to the first amplifier;
a fourth diode that has an anode that is connected to the base or the gate of the third bias transistor, and a cathode that is electrically connected to the emitter or the source of the third bias transistor;
an eighth resistor circuit element that has a first end that is connected to the anode of the fourth diode, and a second end that is connected to the cathode of the fourth diode; and
a capacitor that has a first end that is connected to the anode of the fourth diode, and a second end that is connected to ground,
wherein the cathode of the fourth diode is electrically connected to ground.
